(19) United States
(12) Patent Application Publication
(10) Pub. No.: US 2014/0362526 A1
(43) Pub. Date: Dec. 11, 2014

(54) SERVER SYSTEM AND HEAT-DISSIPATION METHOD OF THE SAME

(71) Applicants: INVENTEC CORPORATION, Taipei City (TW); Inventec (Pudong) Technology Corporation, Shanghai (CN)

(72) Inventor: Hao-Hao WANG, SHANGHAI (CN)

(73) Assignees: INVENTEC CORPORATION, Taipei City (TW); Inventec (Pudong) Technology Corporation, Shanghai (CN)

(21) Appl. No.: 14/183,536

(22) Filed: Feb. 19, 2014

(30) Foreign Application Priority Data
Jun. 7, 2013 (CN) 201310224901.4

(51) Int. Cl. H05K 7/20

(52) U.S. Cl. CPC H05K 7/20836; H05K 7/20736
USPC 361/679.48

(57) ABSTRACT

A server system is provided. The server system includes at least one fan module, a plurality of server nodes and a system management module. Each of the server nodes includes at least one sensor and a node management chip. The sensor detects temperature information of the server node. The node management chip stores an algorithm and retrieves the temperature information to calculate a node fan speed value according to the algorithm. The system management module manages the server system, retrieves the node fan speed values from the node management chip of each of the server nodes, generates at least one coordinated fan speed value according to the node fan speed values and controls the speed of the fan module according to the coordinated fan speed value to perform heat dissipation for the server node.

### RELATED APPLICATIONS

This application claims priority to Chinese Application Serial Number 201310224901.4, filed Jun. 7, 2013, which is herein incorporated by reference.

### BACKGROUND

1. Field of Disclosure

The present disclosure relates to a server technology. More particularly, the present disclosure relates to a server system and a heat-dissipation method of the same.

2. Description of Related Art

In the modem life, the network is an indispensable way of information communication and exchange. As an important tool to provide network services, a server must have a capability to process large amounts of data. Thus, whether in the data processing capability or the heat-dissipation capability, the server must be designed well to achieve the most effective management.

Owing to demands for large amounts of data, plural servers are generally packaged together and managed by a center-managed module. For example, this center-managed module can control the speed of a fan module according to the environment information such as temperature of the sensor in each of servers to achieve the heat-dissipation effect. However, in the condition of the number of servers accommodated in the server system being increased, the amount of environment information trends to increase as well, which will become a load for the data throughput in the system. Furthermore, when the server architecture in the server system is adjusted or modified, the heat-dissipation algorithm of the center-managed module also needs to be adjusted to achieve the optimal heat-dissipation effect. Thus, even a small modification may cause a need to re-update the algorithm by the center-managed module, resulting in increased maintenance costs.

Thus, it is a problem demanding prompt solution in the industry how to design a novel server system and a heat-dissipation method of the same to overcome the aforesaid problems.

### SUMMARY

In view of the above, one aspect of the present disclosure provides a server system, including: a fan module, a plurality of server nodes and a system management module. Each of the server nodes includes at least one sensor and a node management chip. The sensor is configured for detecting temperature information of the server node. The node management chip stores an algorithm and is configured for retrieving the temperature information and calculating a node fan speed value according to the algorithm. The system management module manages the server system, retrieves the node fan speed value from the node management chip of each of the server nodes, generates at least one coordinated fan speed value according to the node fan speed value and controls the speed of the fan module according to the coordinated fan speed value to perform heat-dissipation for the server nodes.

According to an embodiment of the present disclosure, the server system further includes at least one auxiliary sensor disposed in the server system to detect auxiliary environment information. The system management module further calculates an auxiliary fan speed value according to the auxiliary environment information to generate a coordinated fan speed value according to the node fan speed value of each of the server nodes and/or the auxiliary fan speed value. The auxiliary sensor is disposed in the air outlet.

According to another embodiment of the present disclosure, the auxiliary environment information includes voltage information, current information or a combination thereof.

According to a further embodiment of the present disclosure, the server system includes a first heat-dissipation space and a second heat-dissipation space. The first heat-dissipation space corresponds to a plurality of first server nodes and a first fan module, and the second heat-dissipation space corresponds to a plurality of second server nodes and a second fan module. The system management module generates a first coordinated fan speed value according to the node fan speed value provided by the first server nodes, so as to control the first fan module to perform heat-dissipation in the first heat-dissipation space. The system management module generates a second coordinated fan speed value according to the node fan speed value provided by the second server nodes, so as to control the second fan module to perform heat-dissipation in the second heat-dissipation space.

According to still another embodiment of the present disclosure, the system management module detects whether the first server node and the second server node are inserted into the first heat-dissipation space and the second heat-dissipation space. if the first server node is inserted into the first heat-dissipation space while the second server node is not inserted into the second heat-dissipation space, then the first coordinated fan speed value is generated according to the node fan speed value provided by the first server nodes to control operation of the first fan module, and the operation of the second fan module is controlled according to a preset anti-reflux speed value. If the system management module detects that a server node is inserted into the first heat-dissipation space or the second heat-dissipation space but the system management module does not retrieve the node fan speed value of any certain server node, then the operation of the fan module corresponding to the server node is controlled according to a safe speed value.

According to still a further embodiment of the present disclosure, the node management chip is a baseboard management controller. The system management module communicates with the node management chip of the server nodes through an intelligent platform management bus (IPMB) or an I²C interface.

In view of the above, one aspect of the present disclosure provides a heat-dissipation method, including: a plurality of server nodes in the server system each detecting a temperature information of the server node through at least one sensor; a node management chip of each of the server nodes retrieving the temperature information to calculate a node fan speed value according to an algorithm stored in the node management chip; a system management module of the server system retrieving the node fan speed values respectively from the node management chip of each of the server nodes , and generating at least one coordinated fan speed value according to the node fan speed values; and the system management module controlling the speed of at least one fan module according to the at least one coordinated fan speed value to perform heat-dissipation for the server nodes.

According to an embodiment of the present disclosure, the heat-dissipation method further includes: the system management module calculating an auxiliary fan speed value further according to at least one auxiliary environment information detected by at least one auxiliary sensor; and generating the at least one coordinated fan speed value according to the node fan speed values of each of the server nodes and/or the auxiliary fan speed value.

According to another embodiment of the present disclosure, the auxiliary sensor is disposed in the air outlet.

### BRIEF DESCRIPTION OF THE DRAWINGS

FIG. 1 is a block diagram of a server system according to an embodiment of the present disclosure;

FIG. 2 is a more detailed block diagram of a server system according to an embodiment of the present disclosure;

FIG. 3 is a block diagram of a server system according to another embodiment of the present disclosure; and

FIG. 4 is a flow chart of a heat-dissipation method used in a server system according to an embodiment of the present disclosure.

### DETAILED DESCRIPTION

Reference is made to FIG. 1. FIG. 1 is a block diagram of a server system 1 according to an embodiment of the present disclosure. The server system 1 includes a fan module 10, a plurality of server nodes 120, 122, 124 and 126, and a system management module 14.

In this embodiment, the fan module 10 includes four fans 100, 102, 104 and 106. In other embodiments, the number of the fans included in the fan module 10 can be adjusted depending upon actual conditions.

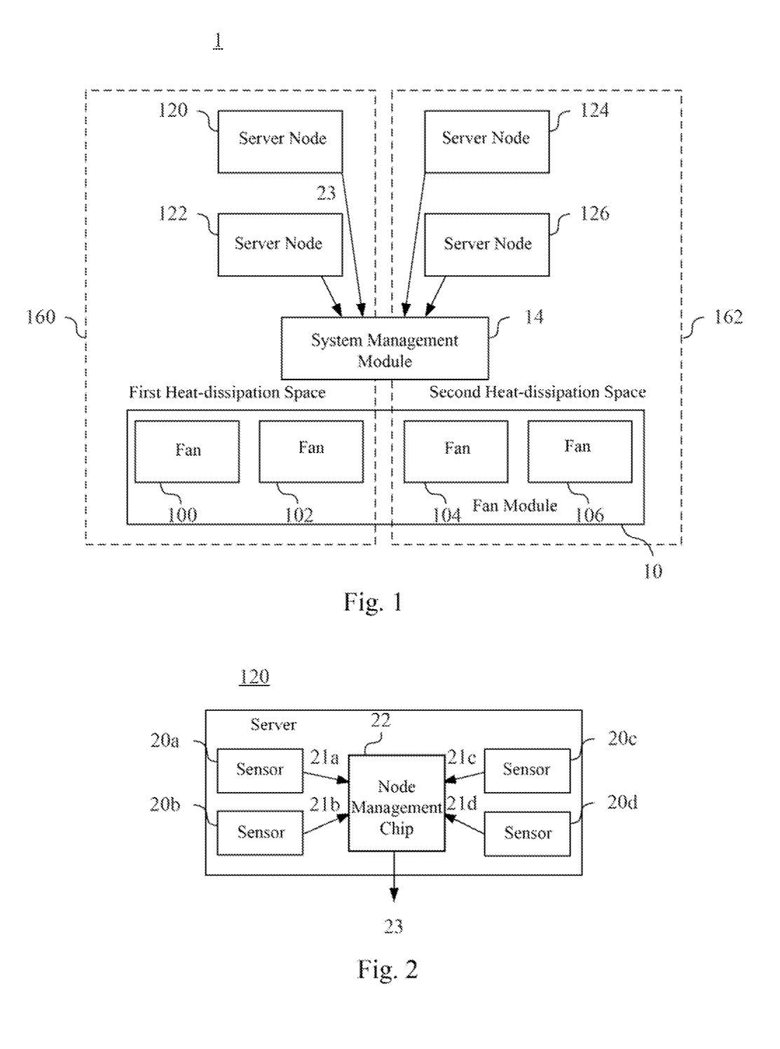

Reference is also made to FIG. 2. FIG. 2 is a more detailed block diagram of the server node 120 according to an embodiment of the present disclosure. It should be noted that the server nodes 122-126 may have the same architecture as the server node 120, and may also have different element arrangement depending upon the condition. The server node 120 may be composed of a motherboard (not shown) and elements included thereon. The server node 120 includes sensors 20a, 20b, 20c, 20d and a node management chip 22. The sensors 20a-20d are configured for detecting the temperature information 21a, 21b, 21c and 21d. In an embodiment, the temperature information 21a-21d may include for example, temperature information, voltage information, current information or a combination thereof, but the disclosure is not limited to the above. The sensors 20a-20d may be distributed within the server node 120 to retrieve the temperature information 21a-21d within the whole server node 120. In a different embodiment, the number of the sensors can be adjusted depending upon the actual conditions. The disclosure is not limited to the number as shown in FIG. 2.

The node management chip 22 is configured for retrieving the temperature information 21a-21d to calculate a node fan speed value 23. The node management chip 22 can calculate the node fan speed value 23 according to an algorithm stored in the node management chip 22, and the algorithm can be directly or remotely updated whenever necessary. In a different embodiment, the node management chip 22 may be a baseboard management controller or other types of management chips. In an embodiment, this speed value may be a pulse width modulation value of a pulse width modulation (PWM) module (not shown) used to modulate the fan module.

The system management module 14 is configured for communicating with the server nodes 120-126 for management. In an embodiment, the system management module 14 may be a cabinet management controller, and may communicate with the server nodes 120-126 via for example, the intelligent platform management bus (IPMB) or the I²C interface, but the disclosure is not limited to the above. When all of the server nodes 120-126 are configured with the node management chip 22 as shown in FIG. 2 and the node fan speed values (such as the node fan speed value 23 as shown in FIG. 1) has been calculated according to the temperature information 21a-21d, the system management module 14 may retrieve the node fan speed values through the communication interface described above, generate at least one coordinated fan speed value (not shown) according to the node fan speed values, and control the speed of the fan module 10 according to the coordinated fan speed value, so as to perform the heat-dissipation for the server nodes 120-126. In a different embodiment, the coordinated fan speed value may be generated by coordinating according to the node fan speed values and/or other corresponding parameters.

In an embodiment, the system management module 14 may, according to the node fan speed values from all the server nodes 120-126, control the fan module 10 to directly perform the heat-dissipation for the whole system. In another embodiment, the system management module 14 may also divide the whole system into several heat-dissipation spaces for respective management. For example, the system management module 14 may divide the server system 1 as shown in FIG. 1 into a first heat-dissipation space 160 including the server nodes 120 and 122 (may be referred to as first server nodes), and a second heat-dissipation space 162 including the server nodes 124 and 126 (may be referred to as second server nodes). After the node fan speed values of each of the server nodes 120-126 are retrieved, the system management module 14 can generate a first coordinated fan speed value according to the node fan speed values of the server nodes 120 and 122 in the first heat-dissipation space 160 so as to control the corresponding fans 100 and 102 (may be referred to as first fans), and can generate a second coordinated fan speed value according to the node fan speed values of the server nodes 124 and 126 in the second heat-dissipation space 162 so as to control the corresponding fans 104 and 106 (may be referred to as second fans), to achieve a better regional management effect.

In an embodiment, the server system 1 may achieve the management effect through a more flexible way. The system management module 14 may detect whether server nodes are respectively inserted into the first heat-dissipation space 160 and the second heat-dissipation space 162. If a server node is inserted into the first heat-dissipation space 160 while no server node is inserted into the second heat-dissipation space 162, then the system management module 14 may generate the first coordinated fan speed value according to the node fan speed values provided by the server nodes in the first heat-dissipation space 160 to control the operation of the fan modules 100 and 102, and control the operation of the fan modules 104 and 106 according to a preset anti-reflux speed value.

Since the first heat-dissipation space 160 and the second heat-dissipation space 162 may be connected, the above mentioned preset anti-reflux speed value is used for generating a certain quantity of wind by the fan modules 104 rid 106 to prevent some wind in the first heat-dissipation 160 from reversely flowing out from the second heat-dissipation space 162.

In another embodiment, if the system management module 14 detects that a server node is inserted into the first heat-dissipation space 160 or the second heat-dissipation space 162 but the node fan speed value of at least one server node is not retrieved, then the system management module 14 controls operation of the fan module corresponding to the server node according to a safe speed value.

The server system of the present disclosure can retrieve the environment information of the sensors through the node management chip in each of the server nodes, automatically calculate the node fan speed value and then transmit the node fan speed value to the system management module. The system management module then generates the coordinated fan speed value according to the calculated node fan speed value to control the speed of the fan module. Thus, on the one hand, the system management module does not need to retrieve large amounts of temperature information through the node management chip of each of the servers, but only needs to retrieve the node fan speed value. As a result, the information throughput between the system management module and the server nodes can be significantly reduced. On the other hand, since the node fan speed value can be calculated via the node management chip in each of the server nodes, the update of the heat-dissipation algorithm hereafter can be achieved by respectively adjusting each of the server nodes, without substantially changing the software in the system management module.

Another advantage is that in the traditional server system, if each node type is different, then the format of the temperature information transmitted by the node may be also different. Thus, the corresponding information format should be predefined in a firmware of the management module to enable the management module to identify various types of node information, which increases the complexity of the firmware. Furthermore, if the node type is changed, then the firmware of the management module needs to be re-updated as well.

It should be noted that in fact, according to the temperature information, each of the servers can also calculate the control information of other heat-dissipation modules (such as a water-cooling system) that may be disposed in the system and then transmit the control information to the system management module by the similar way so as to control the corresponding heat-dissipation module.

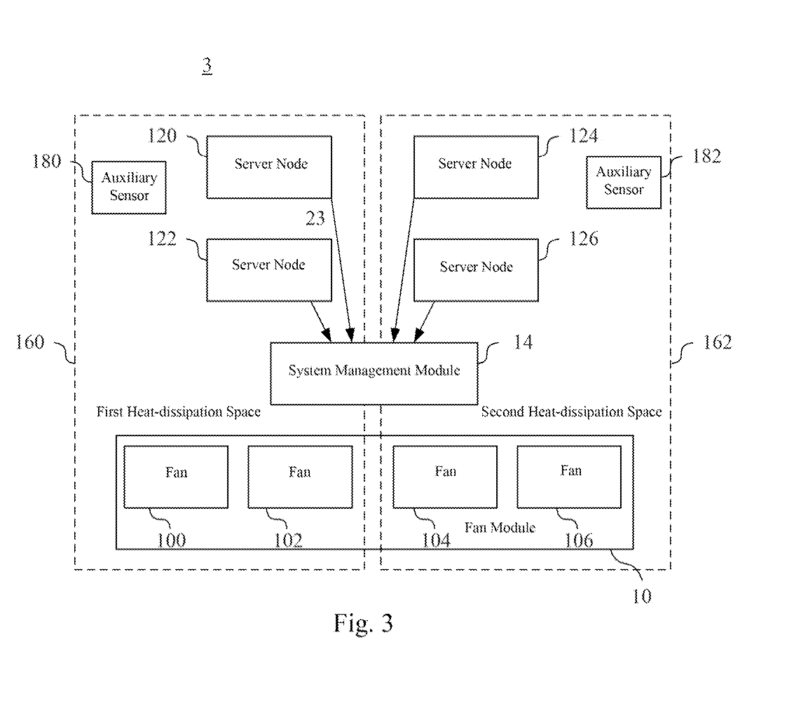

Reference is made to FIG. 3, FIG. 3 is a block diagram of a server system 3 according to another embodiment of the present disclosure. The server system 3 is much the same as the server system 1 as shown in FIG. 1, and thus the same elements included therein will not be described here anymore. In this embodiment, the server system 3 further includes auxiliary sensors 180 and 182 disposed around the server nodes 120-126.

In a different embodiment, the number of the auxiliary sensors 180 and 182 can be adjusted depending upon the condition, and the disclosure is not limited to the number as shown in FIG. 3. In an embodiment, the auxiliary sensors 180 and 182 may be disposed in for example, the air outlet of the system, but not limited to the above, so as to detect the auxiliary environment information (not shown), Similarly, the auxiliary environment information may include for example, voltage information, current information or a combination thereof, but not limited to the above. The system management module 14 retrieves the auxiliary environment information from the auxiliary sensors 180 and 182 to calculate the auxiliary node fan speed value according to the auxiliary environment information and generates the at least one coordinated fan speed value based on the node fan speed value transmitted from each of the server nodes 120-126 and/or the auxiliary node fan speed value. With the coordination and adjustment of the node fan speed value and/or the auxiliary node fan speed value, the system management module 14 can control the speed of the fan module 10 according to the coordinated fan speed value in order to achieve the heat-dissipation mechanism of the system.

Since some of the server nodes in the system may not have such a node management chip as the baseboard management controller, or the node management chip of some server nodes in the system may not normally operate (for example, not powered on, not properly installed or damaged), the node fan speed value cannot be fed back to the system management module. At the moment, the system management module can retrieve the auxiliary environment information according to the auxiliary sensor disposed around the server, and ensure that when the data of the node fan speed value cannot be entirely obtained, the temperature of the system can still be controlled within a reasonable range and the reflux can be avoided.

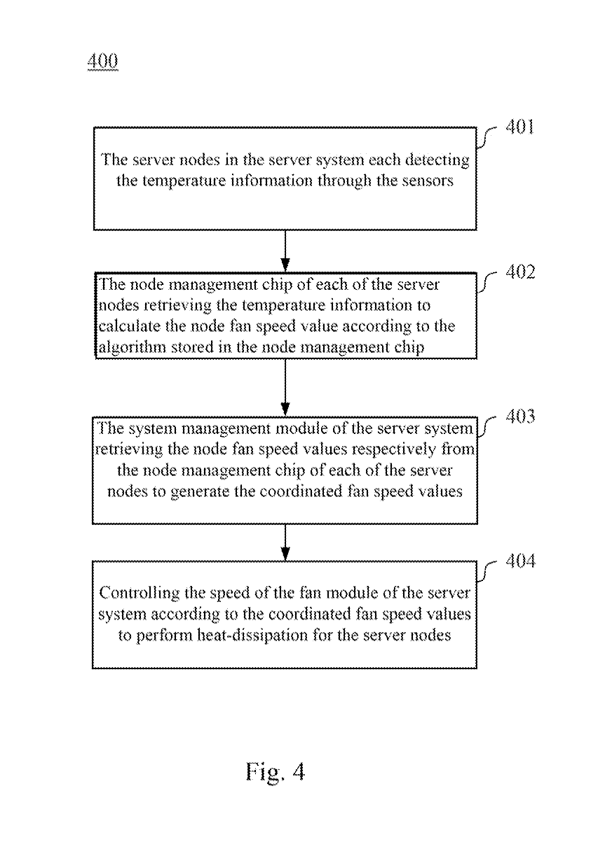

Reference is made to FIG. 4. FIG. 4 is a flow chart of a heat-dissipation method 400 according to an embodiment of the present disclosure. The heat-dissipation method 400 can be used in the server system 1 as shown in FIG. 1 or the server system 3 as shown in FIG. 3. The heat-dissipation method 400 includes the following steps.

In step 401, the temperature information 21a-21d is respectively detected through the sensors 20a-20d of the server nodes 120-126 in the server system

In step 402, the node management chip 22 of each of the server nodes 120-126 retrieves the temperature information 21a-21d to calculate the node fan speed value 23 according to the algorithm stored in the node management chip 22.

In step 403, the system management module 14 in the server system 1 retrieves the node fan speed value 23 respectively from the node management chip 22 of each of the server nodes 120-126, so as to generate at least one coordinated fan speed value, and in step 404, the system management module 14 controls the speed of the fan module 10 in the server system 1 according to the coordinated fan speed value to perform heat-dissipation for the server nodes 120-126.

It should be noted that in the embodiments described above, the cabinet system and the server nodes managed thereby are taken as examples for illustration, and in other embodiments, the illustration may also be applicable to for example a blade server system, or other server systems, which is not limited to the examples of the present embodiment.

Although the present disclosure has been disclosed with reference to the above embodiments, these embodiments are not intended to limit the present disclosure. It will be apparent to those of skills in the art that various modifications and variations can be made without departing from the spirit and scope of the present disclosure. Therefore, the scope of the present disclosure shall be defined by the appended claims.

What is claimed is:

1. A server system, comprising:
at least one fan module;
a plurality of server nodes, each of the plurality of server nodes comprising:
at least one sensor configured for detecting a temperature information of the server node; and
a node management chip storing an algorithm therein, configured for retrieving the temperature information and calculating a node fan speed value according to the algorithm; and
a system management module configured for managing the server system, retrieving the node fan speed values from the node management chip of each of the server nodes, generating at least one coordinated fan speed value according to the node fan speed values and controlling the speed of the fan module according to the at least one coordinated fan speed value to perform heat-dissipation for the server nodes.

2. The server system of claim 1, further comprising at least one auxiliary sensor disposed in the server system, configured for detecting an auxiliary environment information, wherein the system management module further calculates an auxiliary fan speed value according to the auxiliary environment information to generate the at least one coordinated fan speed value according to the node fan speed values of each of the server nodes and/or the auxiliary fan speed value.

3. The server system of claim 2, wherein the auxiliary sensor is disposed in an air outlet of the server system.

4. The server system of claim 2, wherein the auxiliary environment information comprises a voltage information, a current information or a combination thereof.

5. The server system of claim 1, wherein the server system comprises a first heat-dissipation space corresponding to a plurality of first server nodes and a first fan module, and a second heat-dissipation space corresponding to a plurality of second server nodes and a second fan module;
the system management module generates a first coordinated fan speed value according to the node fan speed value provided by the first server nodes, so as to control the first fan module to perform heat-dissipation in the first heat-dissipation space;
the system management module generates a second coordinated fan speed value according to the node fan speed value provided by the second server nodes, so as to control the second fan module to perform heat-dissipation in the second heat-dissipation space.

6. The server system of claim 5, wherein the system management module detects whether the first server nodes and the second server nodes are inserted into the first heat-dissipation space and the second heat-dissipation space, and if the first server nodes are inserted into the first heat-dissipation space while the second server nodes are not inserted into the second heat-dissipation space, then a first coordinated fan speed value is generated according to the node fan speed value provided by the first server nodes to control the operation of the first fan module, and the operation of the second fan module is controlled according to a preset anti-reflux speed value.

7. The server system of claim 6, wherein if the system management module detects that a server node is inserted into the first heat-dissipation space or the second heat-dissipation space but the system management module does not retrieve the node fan speed value of any certain server node, then the operation of the fan module corresponding to the server node is controlled according to a safe speed value.

8. The server system of claim 1, wherein the node management chip is a baseboard management controller.

9. The server system of claim 1, wherein the system management module communicates with the node management chip of the server nodes through an intelligent platform management bus (IPMB) or an I²C interface.

10. A heat-dissipation method used in a server system, comprising:
a plurality of server nodes in the server system each detecting a temperature information of the server node through at least one sensor;
a node management chip of each of the server nodes retrieving the temperature information to calculate a node fan speed value according to an algorithm stored in the node management chip;
a system management module of the server system retrieving the node fan speed values respectively from the node management chip of each of the server nodes , and generating at least one coordinated fan speed value according to the node fan speed values; and
the system management module controlling the speed of at least one fan module according to the at least one coordinated fan speed value to perform heat-dissipation for the server nodes.

11. The heat-dissipation method of claim 10, further comprising:
the system management module calculating an auxiliary fan speed value further according to at least one auxiliary environment information detected by at least one auxiliary sensor;
generating the at least one coordinated fan speed value according to the node fan speed values of each of the server nodes and/or the auxiliary fan speed value.

12. The heat-dissipation method of claim 11, wherein the auxiliary sensor is disposed in an air outlet.

13. The heat-dissipation method of claim 10, wherein the server system comprises a first heat-dissipation space corresponding to a plurality of first server nodes and a first fan module, and a second heat-dissipation space corresponding to a plurality of second server nodes and a second fan module, the heat-dissipation method further comprises:
the system management module generating a first coordinated fan speed value according to the node fan speed value provided by the first server nodes to control the first fan module to perform heat-dissipation in the first heat-dissipation space; and
the system management module generating a second coordinated fan speed value according to the node fan speed value provided by the second server nodes to control the second fan module to perform heat-dissipation in the second heat-dissipation space.

14. The heat-dissipation method of claim 13, further comprising:
the system management module detecting whether the first server nodes and the second server nodes are inserted into the first heat-dissipation space and the second heat-dissipation space;
if the first server nodes are inserted into the first heat-dissipation space while the second server nodes are not inserted into the second heat-dissipation space, then generating a first coordinated fan speed value according to the node fan speed value provided by the first server nodes to control the operation of the first fan module, and controlling the operation of the second fan module according to a preset anti-reflux speed value.

15. The heat-dissipation method of claim 14, further comprising:
if the system management module detects that a server node is inserted into the first heat-dissipation space or the second heat-dissipation space but the system management module does not retrieve the node fan speed value of any certain server node, then controlling operation of the fan module corresponding to the server node according to a safe speed value.
